(19) United States
(12) Patent Application Publication
(10) Pub. No.: US 2013/0266742 A1
(43) Pub. Date: Oct. 10, 2013

(54) CHEMICAL VAPOR DEPOSITION APPARATUS FOR SYNTHESIZING DIAMOND FILM AND METHOD FOR SYNTHESIZING DIAMOND FILM USING THE SAME

(71) Applicant: KOREA INSTITUTE OF SCIENCE AND TECHNOLOGY, (US)

(72) Inventors: Young Joon BAIK, Seoul (KR); Jong Keuk PARK, Seoul (KR); Wook Seong LEE, Seoul (KR)

(73) Assignee: KOREA INSTITUTE OF SCIENCE AND TECHNOLOGY, Seoul (KR)

(21) Appl. No.: 13/728,170

(22) Filed: Dec. 27, 2012

(30) Foreign Application Priority Data
Apr. 10, 2012 (KR) 10-2012-0037503

(51) Int. Cl. C23C 16/27

(52) U.S. Cl. CPC C23C 16/27
USPC 427/577; 118/715; 118/723 HC; 118/723 R; 427/249.8; 427/249.11

(57) ABSTRACT

The present disclosure relates to a chemical vapor deposition apparatus for synthesizing a diamond film and a method for synthesizing a diamond film using the same, which maintains the substrate temperature at an optimum level by suppressing the rise of a substrate temperature, and, thus, improves the degree of activation of a diamond synthesizing gas to increase a diamond growth rate when synthesizing a diamond film. The chemical vapor deposition apparatus for synthesizing a diamond film according to the present disclosure includes a chamber in which a chemical vapor deposition process is performed, a substrate provided in the chamber and giving a place where diamond is grown, and a heat-shielding structure spaced above from the substrate, wherein the heat-shielding structure includes an opening through which a precursor gas is transferable.

### CROSS-REFERENCE TO RELATED APPLICATION

This application claims priority to Korean Patent Application No. 10-2012-0037503, filed on Apr. 10, 2012, and all the benefits accruing therefrom under 35 U.S.C. §119, the contents of which in its entirety are herein incorporated by reference.

### BACKGROUND

1. Field

The present disclosure relates to a chemical vapor deposition apparatus for synthesizing a diamond film and a method for synthesizing a diamond film using the same, and more particularly, to a chemical vapor deposition apparatus for synthesizing a diamond film and a method for synthesizing a diamond film using the same, which may suppress the rise of a substrate temperature and improve the degree of activation of a diamond synthesizing gas to increase a diamond growth rate when synthesizing a diamond film.

2. Description of the Related Art

Diamond has various and excellent physical properties. Among existing substances, diamond has the highest hardness, the highest thermal conductivity and good light transparency across a wide wavelength range, and so it may be applied in various fields. Diamond may be artificially synthesized by means of a high pressure high temperature synthesis method (HPHT) and chemical vapor deposition (CVD) (K. Kobashi, Diamond Films: Chemical Vapor Deposition for Oriented and Heteroepitaxial Growth, Elsevier, 2005). In the HPHT, diamond is synthesized in a powder shape, and in the CVD, diamond has a film shape coated on a substrate. Therefore, the CVD is more suitable method for various industrial applications.

In case of diamond synthesis, CVD may be applied in two ways. In one way, a film with a thickness of several pm is coated to a component and then used, and in the other way, diamond is synthesized as a thick film with a thickness of several hundreds pm or above to be used as a diamond thick film itself. In both cases, a diamond growth rate is an important factor in a production cost. In particular, in case of using the thick film as a product, the growth rate of the film is most important for the production cost.

A diamond synthesizing method using CVD is classified into a low-pressure synthesizing method where diamond is synthesized at a pressure of several ten torr and a high pressure synthesizing method where diamond is synthesized at 100 torr or above. At this high pressure, the plasma tends to shrink and form a ball-like shape (hereafter we call it a plasma ball) and thus more power should be applied to enlarge the plasma ball size. Here, as the plasma pressure is higher, the growth rate increases. The low-pressure synthesizing method is generally applied to make a thin film, and the high pressure synthesizing method is generally applied to make a thick film. In the diamond synthesizing method using CVD, a mixed gas of hydrocarbon such as hydrogen (H₂) and methane (CH₄) is activated by means of heat (hot filament chemical vapor deposition, HFCVD) or plasma (plasma assisted chemical vapor deposition, PACVD), and the activated gas is supplied onto a substrate kept at a temperature of 900 to 1000° C. to grow a diamond film.

When synthesizing a diamond film using HFCVD or PACVD, it is very important to keep the substrate at the suitable temperature for diamond formation. In case of HFCVD and PACVD, the substrate is placed on a cooling block to control the temperature of the substrate by means of the cooling block. However, controlling the temperature of a substrate by a cooling block has a limit. In other words, if the temperature of the substrate rises much greater than a suitable temperature maximum, the cooling capacity of a cooling block becomes not sufficient due to the limitation of the heat flow to the cooling block. Accordingly, there is a restriction in raising a tungsten filament temperature of the HFCVD for a high growth rate and the input power consumed for applying plasma to the PACVD, and so it is difficult to improve a diamond growth rate.

In detail, in the HFCVD (see FIG. 1), in a state where a cooling block to which a substrate is mounted is provided at one side in a chamber and a tungsten filament is provided at a location spaced upwards from the substrate, the tungsten filament is heated to 2000° C. or above to synthesize diamond. In the HFCVD, the diamond growth rate is determined by two factors: the filament temperature and the distance between the filament and the substrate. In other words, as the temperature of the tungsten filament is higher, the growth rate increases. In addition, as a distance between the tungsten filament and the substrate is smaller, the growth rate increases. Therefore, in order to increase the diamond growth rate, the power applied to the tungsten filament should be increased to raise the filament temperature and the distance should be reduced. However, since the temperature of the substrate also rises by adopting such methods, there should be a limit in raising the temperature of the tungsten filament as well as reducing the distance. Consequently, a method should be designed to maintain the substrate temperature at an appropriate level.

In case of PACVD (see FIG. 2), in a state where a cooling block on which a substrate is mounted is provided at one side in a chamber, a plasma forms above the cooling block. In the PACVD, in order to improve the diamond growth rate, density and energy of the plasma should be increased. However, since the temperature of the substrate rises with the increase of the plasma energy, there is a limit in increasing the power consumed for forming the plasma ball to maintain the appropriate substrate temperature.

### RELATED LITERATURES

### Non-patent Literature

### K. Kobashi, Diamond Films: Chemical Vapor Deposition for Oriented and Heteroepitaxial Growth, Elsevier, 2005

### SUMMARY

The present disclosure is directed to provide a chemical vapor deposition apparatus for synthesizing a diamond film and a method for synthesizing a diamond film using the same, which may suppress the rise of a substrate temperature and improve the degree of activation of a diamond synthesizing gas to increase a diamond growth rate when synthesizing a diamond film.

In one aspect, there is provided a chemical vapor deposition apparatus for synthesizing a diamond film, which includes: a chamber in which a chemical vapor deposition process is performed; a substrate provided in the chamber and giving a place where diamond is grown; and a heat-shielding structure spaced upwards from the substrate, wherein the heat-shielding structure includes an opening through which a precursor gas is transferable.

The chemical vapor deposition apparatus may be a hot filament chemical vapor deposition (HFCVD) apparatus, a high melting point filament may be provided in an upper space of the chamber, and the heat-shielding structure may be disposed between the high melting point filament and the substrate. In addition, the chemical vapor deposition apparatus may be a plasma assisted chemical vapor deposition (PACVD) apparatus, and the heat-shielding structure may be disposed in a space between a plasma and the substrate.

The heat-shielding structure may include a plurality of open circles arranged at regular intervals, or the opening of the heat-shielding structure may include unit openings with the same geometry, which are repeatedly arranged.

In another aspect, there is also provided a method for synthesizing a diamond film, which includes: providing a chemical vapor deposition chamber having a substrate and a heat-shielding structure disposed at a location spaced upwards from the substrate; and supplying a mixed gas of hydrogen and methane into the chemical vapor deposition chamber so that a diamond film grows on the substrate, wherein the heat-shielding structure includes an opening through which a precursor gas transfers.

The substrate may be adjusted to have a temperature of 900 to 1000° C.

A high melting point filament may be provided in an upper space of the chamber, and the heat-shielding structure may be disposed in a space between the high melting point filament and the substrate. A distance between the high melting point filament and the substrate may be adjustable, and a diamond growth rate may increase as the distance between the high melting point filament and the substrate is smaller.

The heat-shielding structure may be placed in a space between a plasma ball and the substrate. An opening area of the heat-shielding structure may be adjustable for maintaining the suitable temperature under a given filament temperature.

The chemical vapor deposition apparatus for synthesizing a diamond film and the method for synthesizing a diamond film using the same according to the present disclosure gives the following effects.

Since a heat-shielding structure is provided on a substrate to suppress the rise of a substrate temperature due to the increase of the filament temperature or the plasma power for enhancing the activation of the precursor gas, the growth rate as well as the crystallinity of the diamond film are enhanced.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a diagram showing a conventional HFCVD apparatus;

FIG. 2 is a diagram showing a conventional PACVD apparatus;

FIGS. 3a and 3b are plane views showing a heat-shielding structure according to an embodiment of the present disclosure;

FIG. 4 is a diagram showing a HFCVD apparatus adopting the heat-shielding structure of the present disclosure; and

FIG. 5 is a diagram showing a PACVD apparatus adopting the heat-shielding structure of the present disclosure.

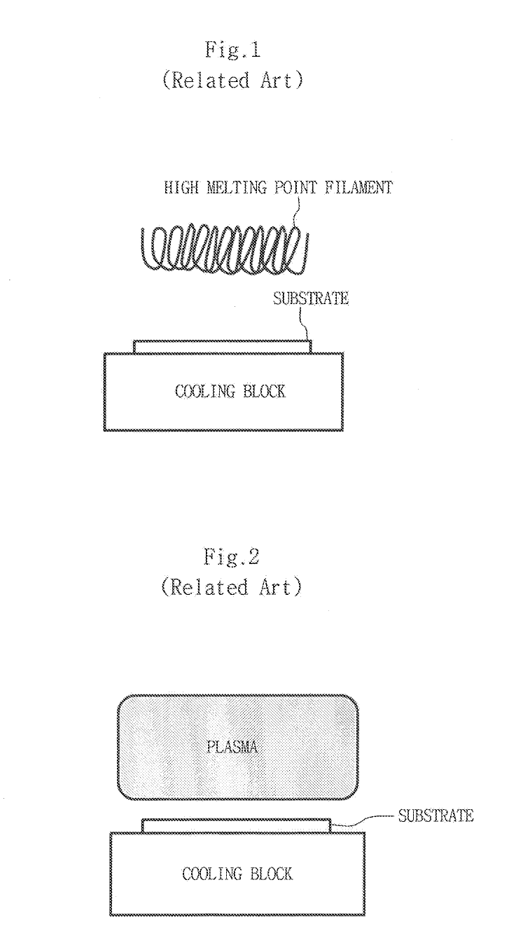

### DETAILED DESCRIPTION OF MAIN ELEMENTS

| | |
|---|---|
| 310: heat-shielding structure | 311: open circle |
| 312: unit opening | |

### DETAILED DESCRIPTION

Exemplary embodiments now will be described more fully hereinafter with reference to the accompanying drawings, in which exemplary embodiments are shown.

In the chemical vapor deposition apparatus for synthesizing a diamond film according to the present disclosure, a diamond growth rate may be increased by restraining the rise of a substrate temperature and maximizing the activation of a precursor gas in a chamber while maintaining the substrate temperature appropriate to diamond formation.

In the chemical vapor deposition process, one of the conditions for increasing the diamond growth rate is to enhance the degree of decomposition and activation of the precursor gas. If the degree of decomposition and activation of the precursor gas is enhanced, carbon atoms are more probably deposited on the substrate as a diamond phase. In order to enhance the degree of decomposition and activation of the precursor gas, the temperature of a high melting point filament or plasma contacting the precursor gas in the chemical vapor deposition process should be increased. If the temperature of the high melting point filament or plasma is increased, the temperature of the substrate heated by the high melting point filament or plasma also rises above an optimum temperature range for diamond deposition, disturbing the growth of diamond. The present disclosure proposes a method giving an effect of enhancing the degree of decomposition and activation to the maximum while maintaining the optimum substrate temperature.

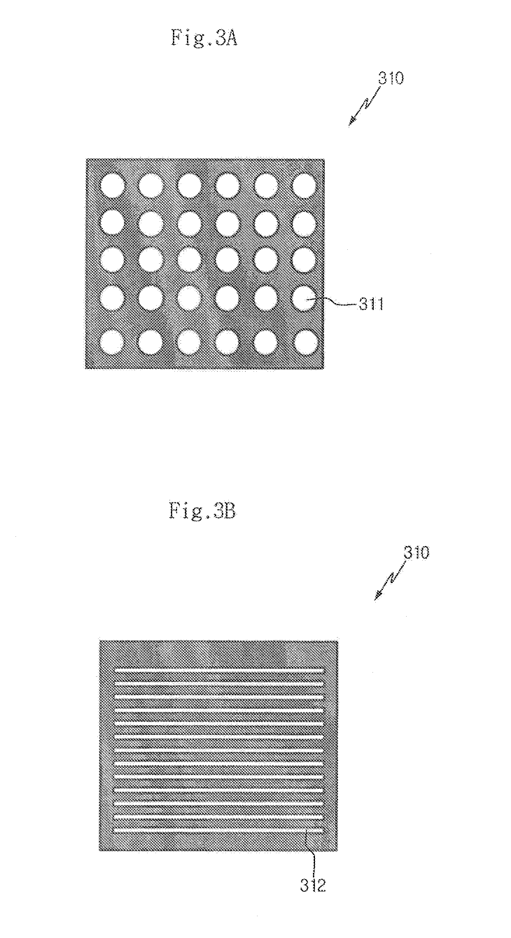

The present disclosure proposes a method of suppressing the rise of the substrate temperature simply by providing a heat-shielding structure at a location spaced upwards from the substrate, which might be caused by increasing the filament temperature or plasma power. The heat-shielding structure 310 has a plate shape and includes an opening with a predetermined area as shown in FIGS. 3a and 3b. The opening area determines the substrate temperature, because the heat is transferred to the substrate though the opening. The opening may be configured with various shapes. For example, the opening may be configured as a plurality of open circles 311 arranged at regular intervals or unit openings 312 having the same width and length and repeatedly arranged in one direction. The heat-shielding structure 310 suppresses the rise of the substrate temperature, and a precursor gas is transferred through the opening and deposited onto the substrate.

The chemical vapor deposition apparatus according to the present disclosure may adopt either hot filament chemical vapor deposition (HFCVD) or plasma assisted chemical vapor deposition (PACVD).

An HFCVD or PACVD apparatus includes a chamber giving a reaction space, and a cooling block provided in the chamber to provide a mounting place of the substrate and controlling a substrate temperature. In addition, a high melting point filament heated by an applied power is provided in the chamber of the HFCVD apparatus, and a plasma generator for forming plasma ball into the upper space of the chamber is provided in the PACVD apparatus.

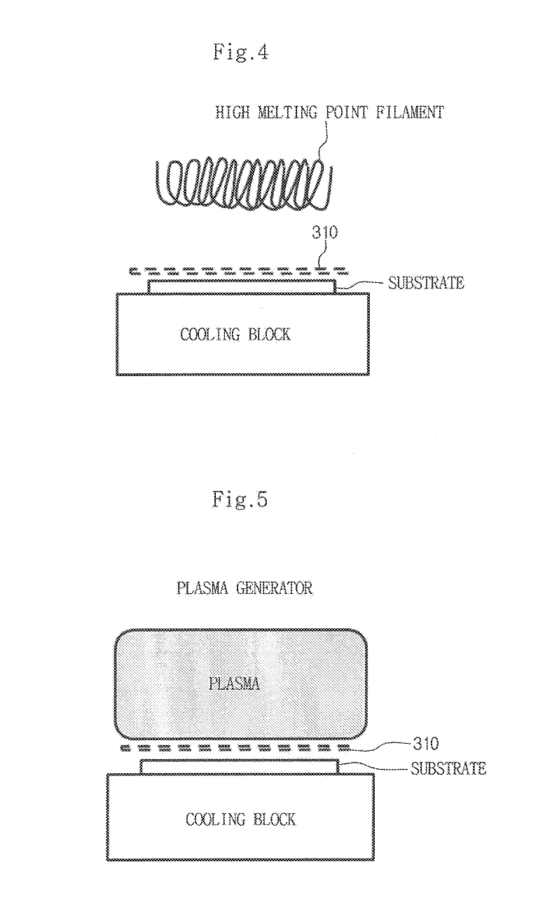

In the HFCVD apparatus, the heat-shielding structure 310 is provided in a space between the high melting point filament and the substrate as shown in FIG. 4 to play a role of suppressing the transfer of a radiant heat from the high melting point filament to the substrate. Since the rise of the substrate temperature is suppressed by the heat-shielding structure 310, it is possible to increase the temperature of the high melting point filament or decrease the distance between the high melting point filament and the substrate while maintaining the optimum substrate temperature, which allows improving a diamond growth rate. The radiant heat reaching the substrate is in proportion to the area of the opening of the heat-shielding structure 310, and accordingly the substrate temperature may be controlled to some degree by adjusting the opening area of the heat-shielding structure 310.

In case of the PACVD apparatus, the heat-shielding structure 310 is provided in a space between the plasma ball generated by a plasma generator, and the substrate as shown in FIG. 5 to play a role of suppressing the rise of the substrate temperature due to plasma heating. As described above, as the rise of the substrate temperature is suppressed by the heat-shielding structure 310, the power consumed for forming plasma may be increased, which allows improving a diamond growth rate.

Hereinafter, a method for synthesizing a diamond film according to the present disclosure will be described in detail based on examples, and properties of the synthesized diamond film will be described.

### Example 1

### Synthesis of Diamond Film Using General HFCVD Method

A diamond film was synthesized on a silicon substrate by using a hot filament CVD (HFCVD) method. The substrate was mounted on a cooling block, a tungsten filament with a diameter of 0.5 mm is provided at a location spaced upwards from the substrate by 1 cm, and ten tungsten filaments are arranged in parallel at an interval of 1 cm. In order to carburize the tungsten filaments, the tungsten filaments were heated by electric resistance heating to have a temperature of 2000° C., a mixed gas where hydrogen (H₂) is mixed with 1 vol % of methane (CH₄) was used as a precursor, and the pressure in the chamber was maintained at 40 torr for 10 hours. The tungsten filament was changed into tungsten carbide after the carburization. The temperature of the tungsten filament for setting the temperature of the substrate to 900° C. at which diamond is synthesized was about 2050° C. Under the above condition, diamond was deposited for 5 hours. The deposited diamond film was measured to have a growth rate of about 0.7 μm/h.

### Example 2

### Synthesis of Diamond Film Using HFCVD Adopting Heat-Shielding Structure

As shown in FIG. 4, a diamond film was synthesized in a state where the heat-shielding structure was mounted to the HFCVD apparatus of Example 1. The heat-shielding structure was provided at a point of 5 mm above the substrate, a plurality of open circles are arranged at regular intervals, each open circle has a width of 8 mm, a distance between centers of adjacent open circles was 12 mm, and the heat-shielding structure had a thickness of 1 mm. The process conditions for synthesizing a diamond film were identically applied to Example 1 except the filament temperature.

After maintaining the tungsten filament to have a temperature of 2000° C. and a pressure of 40 torr for 10 hours, the temperature of the substrate was measured to about 600° C. In order to set the temperature of the substrate to 900° C., the temperature of the tungsten filament was increased to 2450° C., and diamond was deposited for 5 hours. A growth rate of the deposited diamond film was measured to be about 1.8 μm/h.

Compared with Example 1, it may be found that the growth rate of the diamond film is increased over about two times, and this is analogized as being caused by increasing the temperature of the tungsten filament while maintaining the substrate temperature at a suitable temperature (900° C.).

### Example 3

### Reduction of Distance Between Substance and Tungsten Filament

The HFCVD apparatus of Example 2 to which the heat-shielding structure is mounted was used, and diamond was synthesized in a state where the distance between the substrate and the tungsten filament is reduced. The heat-shielding structure was located at a point of 2 mm above the substrate, the distance between the substrate and the tungsten filament was 4 mm, and other process conditions were identically applied to Examples 1 and 2.

When the distance between the substrate and the tungsten filament was 4 mm, the temperature of the substrate might be maintained to be 900° C., and under this condition, diamond was deposited for 5 hours. A growth rate of the deposited diamond film was measured to about 1.2 μm/h, and so it may be understood that the growth rate is increased in comparison to Example 1.

In case of Example 1 where the heat-shielding structure is not applied, the maximum concentration of methane in the precursor for synthesizing diamond is limited to 1.5%. Under the condition where the distance between the substrate and the tungsten filament is 10 mm, similar to Example 1, if the concentration of methane is increased over 1.5%, a graphite phase is formed instead of a diamond phase.

Under the conditions of Example 3 where the heat-shielding structure is applied and the distance between the substrate and the tungsten filament is reduced to 4 mm, the concentration of methane in the precursor may be increased up to 3 vol %, and when the concentration of methane is 3 vol %, the diamond growth rate is about 2.8 μm/h, exhibiting that the diamond growth rate remarkably increases. It is assumed that the concentration of methane may be increased because the probability of depositing diamond atoms on the substrate increases by reducing the distance between the substance and the tungsten filament in a state where the appropriate substrate temperature is maintained.

While the exemplary embodiments have been shown and described, it will be understood by those skilled in the art that various changes in form and details may be made thereto without departing from the spirit and scope of the present disclosure as defined by the appended claims.

What is claimed is:

1. A chemical vapor deposition apparatus for synthesizing a diamond film, comprising:
a chamber in which a chemical vapor deposition process is performed;
a substrate provided in the chamber and giving a place where diamond is grown; and
a heat-shielding structure spaced upwards from the substrate,
wherein the heat-shielding structure includes an opening through which a precursor gas is transferable.

2. The chemical vapor deposition apparatus for synthesizing a diamond film according to claim 1,
wherein the chemical vapor deposition apparatus is a hot filament chemical vapor deposition (HFCVD) apparatus, and
wherein a high melting point filament is provided in an upper space of the chamber, and the heat-shielding structure is disposed between the high melting point filament and the substrate.

3. The chemical vapor deposition apparatus for synthesizing a diamond film according to claim 1,
wherein the chemical vapor deposition apparatus is a plasma assisted chemical vapor deposition (PACVD) apparatus, and
wherein the heat-shielding structure is disposed in a space between the substrate and a plasma ball formed in an upper space of the chamber.

4. The chemical vapor deposition apparatus for synthesizing a diamond film according to claim 1, wherein the heat-shielding structure includes a plurality of open circles arranged at regular intervals.

5. The chemical vapor deposition apparatus for synthesizing a diamond film according to claim 1, wherein the opening of the heat-shielding structure includes unit openings with the same geometry, which are repeatedly arranged.

6. A method for synthesizing a diamond film, comprising:
providing a chemical vapor deposition chamber having a substrate and a heat-shielding structure disposed at a location spaced upwards from the substrate; and
supplying a mixed gas of hydrogen and methane into the chemical vapor deposition chamber so that a diamond film grows on the substrate,
wherein the heat-shielding structure includes an opening through which a precursor gas is transferable.

7. The method for synthesizing a diamond film according to claim 6, wherein the substrate is adjusted to have a temperature of 900 to 1000° C.

8. The method for synthesizing a diamond film according to claim 6, wherein said providing of a chemical vapor deposition chamber provides a chemical vapor deposition chamber having a high melting point filament disposed on the substrate and a heat-shielding structure disposed between the high melting point filament and the substrate.

9. The method for synthesizing a diamond film according to claim 8, wherein a distance between the high melting point filament and the substrate is adjustable, and a diamond growth rate increases as the distance between the high melting point filament and the substrate is smaller.

10. The method for synthesizing a diamond film according to claim 6, wherein the heat-shielding structure is disposed between the substrate and a plasma ball formed in an upper space of the chamber.

11. The method for synthesizing a diamond film according to claim 6, wherein an opening area of the heat-shielding structure is adjustable, and the opening area is in proportion to the temperature of the substrate.
